(19) United States
(12) Patent Application Publication
(10) Pub. No.: US 2024/0069102 A1
(43) Pub. Date: Feb. 29, 2024

(54) A LITHIUM BATTERY POWER DISPLAY METHOD AND SYSTEM

(71) Applicant: GUANGZHOU AUTOMOBILE GROUP CO., LTD., Guangzhou (CN)

(72) Inventors: Beilei Zuo, Guangzhou (CN); Jianyun Peng, Guangzhou (CN); Feng Wei, Guangzhou (CN); Jianwei Lin, Guangzhou (CN); Sai Yang, Guangzhou (CN); Xiongjie Lei, Guangzhou (CN)

(21) Appl. No.: 17/912,195

(22) PCT Filed: Jun. 7, 2022
(86) PCT No.: PCT/CN2022/097408

§ 371 Date: Sep. 16, 2022

(30) Foreign Application Priority Data
Jul. 6, 2021 (CN) 202110763036.5

(51) Int. Cl. G01R 31/367; G01R 31/378; G01R 31/3828

(52) U.S. Cl. CPC G01R 31/367; G01R 31/378; G01R 31/3828

(57) ABSTRACT

A lithium battery power display method and corresponding system, the method includes: during charging process of lithium battery, periodically calculating SOC value charged in this charging through a current integration method (S10); obtaining a sum of the SOC value displayed before charging and the SOC value charged, determining whether it is in a predetermined charging platform area (S11); when determination result is in the predetermined charging platform area and it is determined the correction trigger condition is met, a correction coefficient is calculated according to pre-calibrated formula, the SOC value to be displayed is obtained by correcting the SOC value charged with the correction coefficient, the correction coefficient is positive number less than 1 (S12); displaying the SOC value to be displayed (S13). Solve virtual electricity caused by large SOC error in non-full charge and discharge state of lithium batteries, improve experience of lithium battery electric vehicles.

### TECHNICAL FIELD

The present disclosure relates to the technical field of lithium battery management, in particular to a lithium battery power display method and system.

### BACKGROUND

When the battery is charged at constant current, the change of voltage is rising, stable, and rising. When the battery is charged and discharged at constant current, the voltage is stable, and this stable area is the platform area for charging and discharging. Although it is hoped that the platform area is wider and more stable during the battery power supply process, it is difficult to obtain accurate values in the platform area when measuring the battery state of charge (SOC).

In particular, lithium iron phosphate batteries, which have been used in mass production vehicles in recent years, have been favored by more and more new energy main engine manufacturers because of their low cost, high safety, long cycle life, and greatly improved energy density. However, the open-circuit voltage (OCV) of lithium iron phosphate battery cells show that the platform area is about 30%˜97%, and the estimation of SOC in this area only depends on current integration. Considering the error of sensed current and the consistency of the cells, there is an error in the SOC estimation and it cannot pass the voltage calibration. If the battery is not fully charged for many times in the platform area, a large SOC error may occur, and there is a possibility of false charge. In serious cases, the driver will be left way due to the false charge of the battery.

The existing solutions of the main engine factory generally recommend that the user regularly use his charging device to fully charge the vehicle (it is recommended to fully charge the vehicle at least once a week), and fully charge the vehicle at low electric state (<10% SOC) every 3 months to half a year, or remind the user through mobile phones, meters, etc.

However, there are still users who do not read the user's manual or pay attention to the reminders of mobile phones, meters and other users, or when the SOC error is too large under the condition of not being fully charged for many times due to time problems, which may lead to the embarrassing situation that the battery is left way due to false charge and poor use experience.

### SUMMARY OF THE INVENTION

The object of the present disclosure is to provide a lithium battery power display method and system, which can solve the problem of virtual power caused by excessive SOC error displayed in the state of non-full charge and discharge of lithium battery, thus improving the driver's use experience.

In order to solve the above technical problems, as an aspect of the present disclosure, there is provided a lithium battery power display method, which includes the following steps:
step S10, calculating an SOC value periodically during current charging according to a current integration method in a process of charging the lithium battery;
step S11, obtaining a sum of SOC value displayed before charging and the SOC value charged, and determining whether the sum is within a predetermined charging platform area of the lithium battery;
step S12, calculating and obtaining a correction coefficient according to a pre-calibrated formula, and applying the correction coefficient to correct the SOC value charged, and obtaining an SOC value to be displayed according to the SOC value displayed before charging and a corrected SOC value when battery is within a predetermined charging platform area and a determination is made that the correction trigger condition is reached, wherein the correction coefficient is a positive number less than 1; and
step S13, displaying the SOC value.

Wherein the step S12 further includes:
determining whether the SOC value displayed after last charging is within the predetermined charging platform area after determining that the sum of values is within the predetermined charging platform area; if the SOC value displayed after the last charging is within the predetermined charging platform area, the correction trigger condition is determined to be reached; otherwise, the correction trigger condition is determined to be not reached.

Wherein the step S12 further includes:
calculating the correction coefficient k according to a formula k=ax²+bx+c when the correction trigger condition has been reached; wherein x is the SOC value charged, and constants a, b and c are obtained in advance according to experimentation;
calculating the SOC value to be displayed according to following formula: displayed SOC=SOC displayed before charging+SOC charged*k.

Wherein the step S12 further includes:
determining the sum of the SOC value displayed before charging and the SOC value charged as the SOC value to be displayed when the correction trigger condition is not reached.

Wherein the step S12 further includes:
calculating a current SOC value by a voltage calibration method and determining a calculated current SOC value as the SOC value to be displayed if the sum is not within the predetermined charging platform area of the lithium battery.

Wherein the step S12 further includes:
comparing the calculated current SOC value with an SOC value expected to be displayed in a previous week; obtaining an intermediate value between the calculated current SOC value and the SOC value expected to be displayed in a previous week through a damping algorithm as the SOC value to be displayed if a difference between the calculated current SOC value and the SOC value expected to be displayed in a previous week is greater than a predetermined threshold.

In another aspect of the present disclosure, a system is also provided for correcting a displayed SOC value after charging a lithium battery, the system includes:
a charging SOC value calculation unit configured to calculate a SOC value currently charged in a charge periodically according to a current integration method in a process of charging the lithium battery;
a SOC stage determination unit is configured to obtain a sum of an SOC value displayed before charging and the SOC value charged, and determine whether the sum is in a predetermined charging platform area of the lithium battery;
a correction processing unit configured to calculate and obtain a correction coefficient according to a pre calibrated formula, and apply the correction coefficient to correct the SOC value charged, and obtain an SOC value to be displayed according to the SOC value displayed before charging and a SOC value corrected when a determination result is made that it is within a predetermined charging platform area and the correction trigger condition is determined to be reached; wherein the correction coefficient is a positive number less than 1;
an SOC value display unit configured to display the SOC value to be displayed.
wherein the correction processing unit further includes:
a correction trigger condition determination unit configured to determine the SOC value displayed after last charging is within the predetermined charging platform area after determining that the sum is within the predetermined charging platform area; if the SOC value displayed after the last charging is within the predetermined charging platform area, the correction trigger condition is determined to be reached;
a correction coefficient calculation unit configured to calculate the correction coefficient k according to a formula k=ax²+bx+c when the correction trigger condition of the correction trigger condition determination unit has been reached; wherein x is the SOC value charged, and constants a, b, and c are obtained in advance according to experimentation;
an SOC value to be displayed obtain unit configured to apply the correction coefficient k obtained by the correction coefficient calculation unit and calculate the SOC value to be displayed according to following formula after the determination result of the correction trigger condition determination unit is that the correction trigger condition has been reached;

displayed SOC=SOC displayed before charging+SOC charged*k;
a determination that the sum of the SOC value displayed before charging and the SOC value charged as the SOC value to be displayed after the determination result of the correction trigger condition determination unit determines that the correction trigger condition is not reached.
wherein the system further includes:
a calibration unit configured to calculate a current SOC value by a voltage calibration method and determine a calculated current SOC value as the SOC value to be displayed when the SOC stage determination unit determines that sum is not within the predetermined charging platform area of the lithium battery.

Wherein the calibration unit further includes:
a smoothing processing unit configured to compare the calculated current SOC value with a SOC value expected to be displayed in a previous week, obtaining an intermediate value between the calculated current SOC value and the SOC value expected to be displayed in a previous week through a damping algorithm as the SOC value to be displayed if a difference between the calculated current SOC value and the SOC value expected to be displayed in a previous week is greater than a predetermined threshold.

The present disclosure provides a lithium battery power display method and system. When the SOC value is in a plateau period and the correction trigger condition is met at the same time during each charging, the correction coefficient at this time is calculated according to the SOC charged this time by using a pre-calibrated formula, the current SOC value is negatively corrected by the correction coefficient to deduct a small amount of the charge amount from the displayed SOC value. The accumulated error caused by SOC inaccuracy in the platform period in the prior art can be eliminated by several small deductions from the charging amount.

In the embodiment of the present disclosure, the drivers of electric vehicles using lithium batteries (especially lithium iron phosphate batteries) do not need to pay special attention to reading the user's manual or user's reminders such as mobile phones and meters, they only need to charge at the time when the displayed SOC value reaches the point where charging is required to ensure the safety of power consumption; the present disclosure overcomes the battery virtual charge phenomenon in the prior art, which is caused by excessive SOC error when lithium batteries (especially lithium iron phosphate batteries) are repeatedly not charged to the full, and improves the use experience.

### BRIEF DESCRIPTION OF THE DRAWINGS

In order to more clearly explain the embodiments of the present disclosure or the technical solutions in the prior art, the drawings in the following description should be referred to, but these are only some embodiments of the present disclosure. For those skilled in the art, it is still within the scope of the present disclosure to obtain other drawings according to these drawings without creative labor.

FIG. 1 is a flowchart of a lithium battery power display method according to an embodiment of the present disclosure.

FIG. 2 is a schematic diagram of OCV characteristic zoning of a lithium iron phosphate battery cell in a specific embodiment of the present disclosure.

FIG. 3 is a schematic diagram of a lithium battery power display system according to an embodiment of the present disclosure.

FIG. 4 is a schematic diagram of a correction processing unit in FIG. 3.

FIG. 5 is a schematic diagram of a calibration unit in FIG. 4.

### DETAILED DESCRIPTION

In order to make the purpose, technical scheme and advantages of the present disclosure more clearly, the present disclosure will be further described in detail in combination with the accompanying drawings.

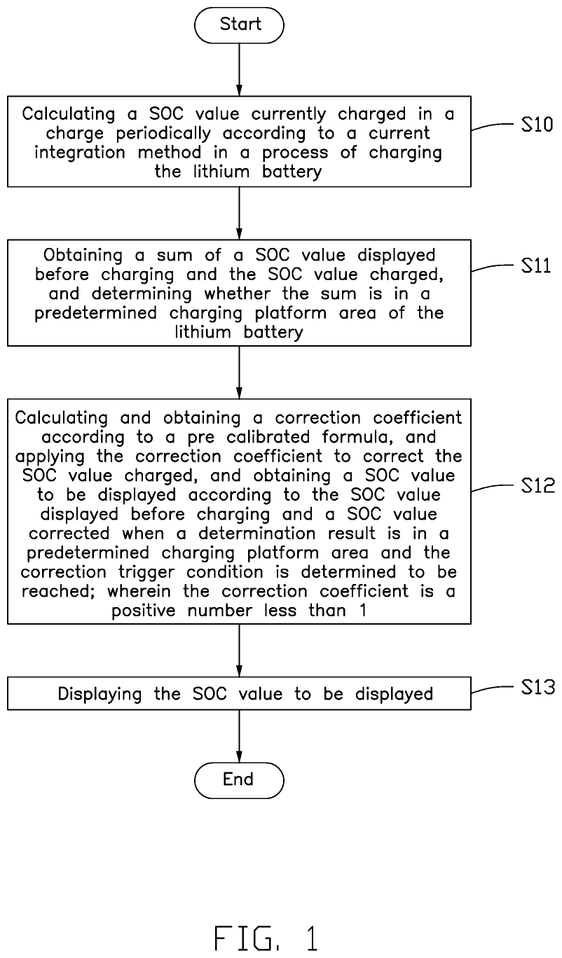

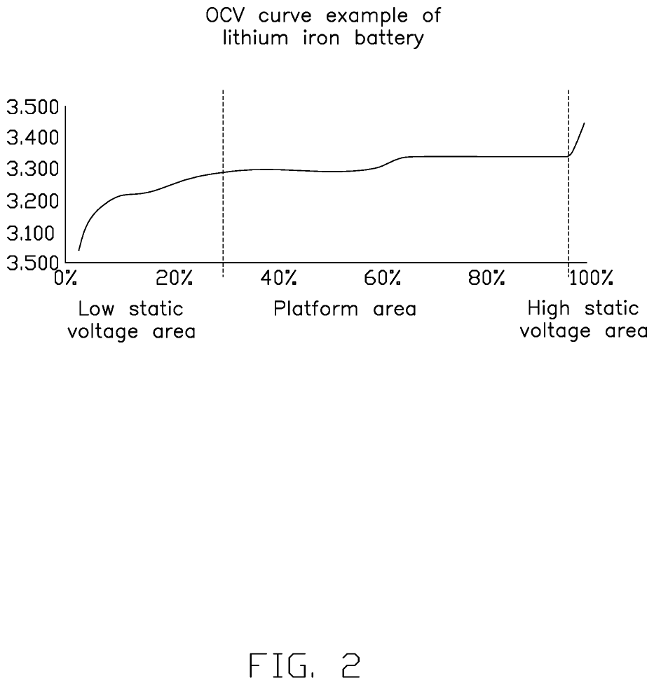

FIG. 1 illustrates a flowchart of a lithium battery power display method according to an embodiment of the present disclosure. The display method of the present disclosure is particularly suitable for batteries with a wide platform area, such as the lithium iron phosphate battery shown in FIG. 2. In the embodiment, the lithium battery power display method includes the following steps:

At step S10, periodically calculating the state of charge (SOC) value as currently charged (for example, 2 minute periods) according to the current integration method in the process of charging the lithium battery; specifically, the charged SOC value is obtained by integrating the current charging current with the current charging duration at the time of this calculation; it should be noted that a first SOC detection needs to be carried out by entering the static voltage area for full/drained power.

At step S11, obtaining a sum of the SOC value displayed before charging and the SOC value charged, and determining whether it is within a predetermined charging platform area of the lithium battery.

The present disclosure can be used for displaying the quantity of electric charge in a lithium battery, especially for displaying the electric quantity of a lithium iron phosphate battery with a wide platform area during charging and discharging, other types of battery charge and discharge display can also be included in estimations of battery charge and discharge in the platform area. FIG. 2 shows the OCV characteristic zoning diagram of the lithium iron phosphate battery cell in the present disclosure; for the lithium iron phosphate battery, the SOC includes low static voltage area, platform area, and high static voltage area, the low static voltage area corresponds to the SOC in the range of 0%˜1%, at this time, the SOC can be corrected according to the voltage; the platform area corresponds to the SOC in the range of L %˜H %, at this time, the voltage calibration cannot be passed, and the SOC can only be calculated by current integration, if this area is charged and discharged back and forth, it is easy to cause a large SOC error, when the SOC error is too large under the condition that the battery is not fully charged for many times, it may lead to the embarrassing situation that the battery is left half way due to the false charge, the present disclosure corrects the displayed SOC value of this area; the high static voltage area corresponds to the SOC in the range of H %˜100%, at this time, it can also be calibrated by voltage correction, and the full state is the best way to eliminate SOC error, in principle, the user should be guided to fully charge. In one example, the L % point is 30%, and the H % point is 97%.

At step S12, calculating and obtaining a correction coefficient according to the pre calibrated formula, and applying the correction coefficient to correct the charged SOC value, and obtaining the SOC value to be displayed according to the SOC value displayed before charging and the corrected SOC value when the determination result is that it is within a predetermined charging platform area and it is also determined that the correction trigger condition has been reached. The correction coefficient is a positive number less than 1.

More specifically, the step S12 further includes:
determining that the SOC value displayed after the last charging is within the predetermined charging platform area after determining that the sum is within the predetermined charging platform area. If yes, it is determined that the correction trigger condition has been reached; otherwise, it is determined that the correction trigger condition is not met.

Wherein the step S12 further incudes:
calculating the correction coefficient k according to the formula k=ax²+bx+c when the correction trigger condition has been reached; where x is the SOC value of the charge, and the constants a, b, and c are obtained in advance according to experimentation.

The k value obtained by the above formula can obtain different correction coefficients at different stages of the charging platform area and refine the correction compensation; it can be understood that the above calculation formula is an example of the formula for obtaining the correction system k, and is not a limitation; in other embodiments, other variations of similar formulas can also be used, for example, first-order formulas can be used to achieve, in these embodiments, the constants in these formulas that need to be adaptively calibrated.

The SOC value to be displayed is calculated according to the following formula:

displayed SOC=SOC displayed before charging+SOC charged*k.

It can be seen from the above formula that the correction coefficient k can be used for negative correction, so that the displayed SOC value is smaller than the actual SOC value.

Wherein the step S12 further incudes:
determining the sum of the SOC value displayed before charging and the SOC value charged as the SOC value to be displayed when the correction trigger condition is not reached.

It can be understood that the purpose of setting the correction trigger condition is to reduce the number of corrections and adapt it when there is frequent charging and discharging occur in the platform area.

At step S13, displaying the SOC value to be displayed.

More specifically, in one embodiment, the step S12 further includes:
calculating the current SOC value through the voltage calibration method and determining the calculated current SOC value as the SOC value to be displayed if the sum is not in the predetermined charging platform area of the lithium iron phosphate battery.

Wherein the step S12 further incudes:
comparing the calculated current SOC value with the SOC value expected to be displayed in the previous week; obtaining the intermediate value of the two through the damping algorithm as the SOC value to be displayed if the difference between the two is greater than a predetermined threshold. The purpose of this step is mainly to large jumps in the displayed SOC so as to improve continuity and smoothness of the displayed SOC. Among them, a variety of algorithms in the prior art can be selected for the damping algorithm, and the threshold value can be set according to actual needs, for example, 5% in one example.

It can be understood that the user of an electric vehicle generally determines whether to charge according to the SOC value, in principle, when the displayed SOC is lower than the psychological expectation, the user will spontaneously charge; if the SOC is not accurate, when the actual SOC is greater than the displayed SOC, the actual range will be more than the displayed range and will not have a negative impact on the user; when the actual SOC is less than the displayed SOC, the actual range will be less than the displayed range (called virtual power), this situation may lead to the driver's misjudgment, resulting in the embarrassing situation of being left halfway due to the battery's false charge.

At the same time, since the error of SOC in the platform area is random, it is impossible to distinguish whether it is a positive deviation or a negative deviation, the user usually determines the range according to the SOC, therefore, in order to avoid the occurrence of virtual power, the SOC correction should be carried out towards the smaller direction, that is, the displayed SOC value should be less than the theoretically calculated SOC value, so that the actual range will be more than the displayed range and will not have a negative impact on the user.

The method adopted in the present disclosure is modified only when the lithium battery is charged. When it is impossible to enter the static voltage area for voltage calibration, the corresponding correction coefficient is obtained according to the information such as the charging current of the platform area (more specifically, the charged SOC value), and the coefficient conversion process is performed on the charged SOC value. That is, the SOC after charging is corrected in the negative direction a few times each time, resulting in the actual displayed SOC value being smaller than the theoretically calculated SOC. Since the charging process is performed a few times, the user will not notice it. After a single charge, the actual SOC charged will be more than the displayed SOC, and the SOC displayed will be smaller than the theoretically-calculated SOC with an increase of charging/discharging times, which can basically cover the SOC error range caused by the charge and discharge in the platform area and prevent the occurrence of false reading.

If it is accumulated to a certain extent, since the displayed value is far less than the theoretical calculation value, the user enters the psychological expectation of charging earlier, and the vehicle is more likely to be fully charged at this time, that is, after entering the static voltage area, the battery can conduct voltage calibration and clear the previous correction value, that is, the display value is equal to the theoretical calculation value. In order to avoid the user's impression that the user's time is significantly shortened, the displayed value can be smoothly transferred to the real SOC value through a certain damping algorithm, and the vehicle can better enter the full power state.

In order to facilitate understanding, the principle of the method of the present disclosure and the effects achieved will be described below by using a specific example. Assuming that 30% is the L % point and 97% is the H % point, the user always charges when the SOC is lower than 40% and stops charging when the SOC is 70%. There will be a random ±1% error in the SOC of each charge and discharge; if no correction is made, the cumulative error of SOC for 1000 times may reach 30%, if the user starts when the SOC is 45%, the user may believe he can reach his destination in theory, but the SOC is 15%, which may lead to the embarrassing situation of losing all power on the way. In case of correction, for convenience of explanation, it is assumed that each correction is −1% (i.e., the correction coefficient k is 0.98), that is, when the SOC is 70% displayed for the first time, the actual theoretical power is 70˜71%, and when the SOC is 70% displayed for the second time, the actual power is 70˜72%, . . . . When the displayed SOC is 70% at the 27th charge, the actual power may be 70˜97%, that is, it is easier to enter the static voltage area, the battery can conduct voltage calibration and guide the user to fully charge in a disguised manner, at this time, if the vehicle shows that the SOC is 45%, the actual theoretical electric quantity must be above 45%, and there will be no virtual electricity; thus, it is possible to avoid the vehicle from running out of power and breaking down halfway, and improve the user's use experience.

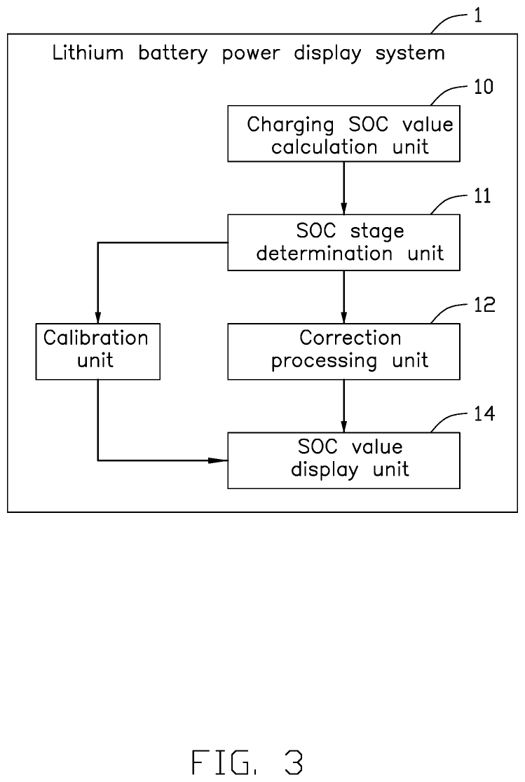

Accordingly, as shown in FIG. 3, another aspect of the present disclosure also provides a lithium battery power display system 1, which includes:

A charging SOC value calculation unit 10 configured to periodically calculate the SOC value charged in the current charging according to the current integration method during the charging process of the lithium battery;

A SOC stage determination unit 11 configured to obtain a sum of the SOC value displayed before charging and the SOC value charged and determine whether it is in a predetermined charging platform area of the lithium battery.

A correction processing unit 12 configured to apply the correction coefficient to correct the charged SOC value and obtain the SOC value to be displayed according to the SOC value displayed before charging and the corrected SOC value when the determination result of the SOC stage determination unit is that it is within a predetermined charging platform area and it is determined that the correction trigger condition has been reached. The correction coefficient is a positive number less than 1.

A calibration unit 13 configured to calculate the current SOC value by the voltage calibration method and determine the calculated current SOC value as the SOC value to be displayed when the SOC stage determination unit determines that the sum of values is not within the predetermined charging platform area of the lithium battery;

An SOC value display unit 14 displays the SOC value to be displayed.

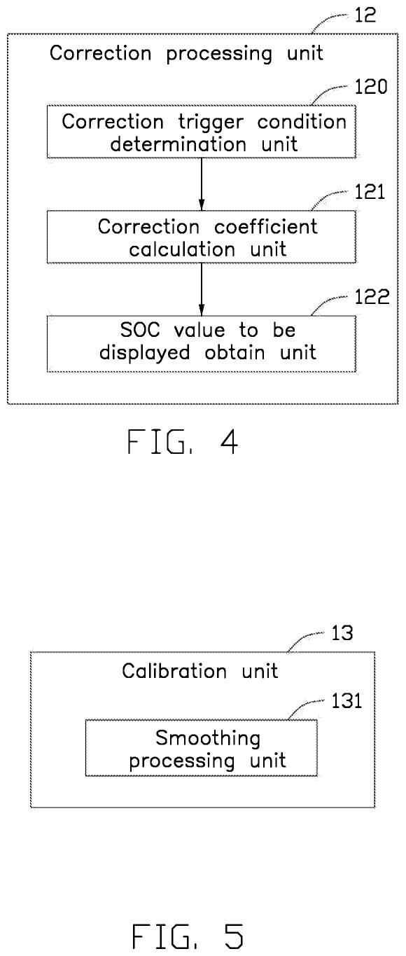

As shown in FIG. 4, the correction processing unit 12 further includes:

The correction trigger condition determination unit 120 configured to determine that the SOC value displayed after the last charging is within the predetermined charging platform area after determining that the sum is in the predetermined charging platform area. If yes, it is determined that the correction trigger condition has been reached.

The correction coefficient calculation unit 21 configured to calculate the correction coefficient k according to the formula k=ax²+bx+c when the determination result of the correction trigger condition determination unit is that the correction trigger condition is reached; where x is the SOC value of the charge, and the constants a, b, and c are obtained in advance according to experimentation.

The SOC value to be displayed obtain unit 122 configured to calculate and obtain the SOC value to be displayed according to the following formula by using the correction coefficient k obtained by the correction coefficient calculation unit after the correction trigger condition determination unit determines that the correction trigger condition has been reached; displayed SOC=SOC displayed before charging+SOC charged*k, and the SOC value to be displayed obtain unit is configured to determine the sum of the SOC value displayed before charging and the SOC value charged as the SOC value to be displayed after the determination result of the correction trigger condition determination unit is that the correction trigger condition is not reached.

As shown in FIG. 5, the calibration unit 13 further includes:

A smoothing processing unit 131 configured to compare the calculated current SOC value with the SOC value expected to be displayed in the previous week, if the difference between the two is greater than a predetermined threshold; if so, the intermediate value of the two is obtained by the damping algorithm as the SOC value to be displayed.

More details are shown in FIG. 1 and FIG. 2, which will not be repeated here.

The embodiments of the present disclosure have the following beneficial effects:

The present disclosure provides a lithium battery power display method and system. When the SOC value is in a plateau period and the correction trigger condition is met at the same time during each charging, the correction coefficient at this time is calculated according to the SOC charged this time by using a pre calibrated formula, the current SOC value is negatively corrected by the correction coefficient to deduct a small amount of the charge amount from the displayed SOC value. The accumulated error caused by the SOC inaccuracy in the platform period in the prior art can be eliminated by several small deductions from the charging amount.

In the embodiment of the present disclosure, the drivers of electric vehicles using lithium batteries (especially lithium iron phosphate batteries) do not need to pay special attention to reading the user's manual or user's reminders such as mobile phones and meters, they only need to charge at the time when the displayed SOC value reaches the point where charging is required to ensure the safety of power consumption; the present disclosure overcomes the problem of battery virtual charge in the prior art, which is caused by excessive SOC error when lithium batteries (especially lithium iron phosphate batteries) are repeatedly not fully charged, and improves the use experience.

Those skilled in the art should understand that embodiments of the present disclosure may be provided as methods, devices, or computer program products. Therefore, the present disclosure may take the form of a full hardware embodiment, a full software embodiment, or an embodiment combining software and hardware aspects. The present disclosure may take the form of a computer program product implemented on one or more computer usable storage media (including but not limited to magnetic disk memory, CD-ROM, optical memory, etc.) containing computer usable program codes.

The present disclosure is described with reference to a flowchart and/or block diagram of a method, apparatus (system), and computer program product according to an embodiment of the present disclosure. It should be understood that each flow and/or block in the flowchart and/or block diagram, and combinations of flow and/or blocks in the flowchart and/or block diagram may be implemented by computer program instructions. These computer program instructions may be provided to a processor of a general-purpose computer, a special-purpose computer, an embedded processor, or other programmable data processing device to generate a machine such that the instructions executed by the processor of the computer or other programmable data processing device generate means for realizing the functions specified in one or more processes of the flowchart and/or one or more blocks of the block diagram.

The above disclosure is only preferred embodiments of the present disclosure, and of course, the scope of the present disclosure cannot be limited by this. Therefore, the equivalent changes made according to the claims of the present disclosure still belong to the scope of the present disclosure.

1. A lithium battery power display method, wherein the method comprising the following steps:
step S10, calculating a SOC value currently charged in a charge periodically according to a current integration method in a process of charging the lithium battery;
step S11, obtaining a sum of a SOC value displayed before charging and the SOC value charged, and determining whether the sum is in a predetermined charging platform area of the lithium battery;
step S12, calculating and obtaining a correction coefficient according to a pre calibrated formula, and applying the correction coefficient to correct the SOC value charged, and obtaining a SOC value to be displayed according to the SOC value displayed before charging and a SOC value corrected when a determination result is in a predetermined charging platform area and the correction trigger condition is determined to be reached; wherein the correction coefficient is a positive number less than 1; and
step S13, displaying the SOC value to be displayed.

2. The method according to claim 1, wherein the step S12 further comprises:
determining whether the SOC value displayed after last charging is within the predetermined charging platform area after determining the sum is in the predetermined charging platform area; if the SOC value displayed after the last charging is within the predetermined charging platform area, the correction trigger condition is determined to be reached; otherwise, the correction trigger condition is determined to be not reached.

3. The method according to claim 2, wherein the step S12 further comprises:
calculating the correction coefficient k according to a formula k=ax²+bx+c when the correction trigger condition has been reached; wherein x is the SOC value charged, and constants a, b and c are obtained in advance according to experimental calibration;
calculating the SOC value to be displayed according to following formula:
displayed SOC=SOC displayed before charging+SOC charged*k.

4. The method according to claim 2, wherein the step S12 further comprises:
determining the sum of the SOC value displayed before charging and the SOC value charged as the SOC value to be displayed when the correction trigger condition is not reached.

5. The method according to claim 1, wherein the step S12 further comprises:
calculating a current SOC value by a voltage calibration method and determining a calculated current SOC value as the SOC value to be displayed if the sum is not in the predetermined charging platform area of the lithium battery.

6. The method according to claim 5, wherein the step S12 further comprises:
comparing the calculated current SOC value with a SOC value expected to be displayed in a previous week; obtaining an intermediate value between the calculated current SOC value and the SOC value expected to be displayed in a previous week through a damping algorithm as the SOC value to be displayed if a difference between the calculated current SOC value and the SOC value expected to be displayed in a previous week is greater than a predetermined threshold.

7. A lithium battery power display system comprising:
a charging SOC value calculation unit configured to calculate a SOC value currently charged in a charge periodically according to a current integration method in a process of charging the lithium battery;
a SOC stage determination unit configured to obtain a sum of a SOC value displayed before charging and the SOC value charged, and determine whether the sum is in a predetermined charging platform area of the lithium battery;
a correction processing unit configured to calculate and obtain a correction coefficient according to a pre calibrated formula, and apply the correction coefficient to correct the SOC value charged, and obtain a SOC value to be displayed according to the SOC value displayed before charging and a SOC value corrected when a determination result is in a predetermined charging platform area and the correction trigger condition is determined to be reached; wherein the correction coefficient is a positive number less than 1; and
a SOC value display unit configured to display the SOC value to be displayed.

8. The system according to claim 7, wherein the correction processing unit further comprises:
a correction trigger condition determination unit configured to determine the SOC value displayed after last charging is within the predetermined charging platform area after determining the sum is in the predetermined charging platform area; if the SOC value displayed after the last charging is within the predetermined charging platform area, the correction trigger condition is determined to be reached;
a correction coefficient calculation unit configured to calculate the correction coefficient k according to a formula k=ax²+bx+c when the correction trigger condition of the correction trigger condition determination unit has been reached; wherein x is the SOC value charged, and constants a, b and c are obtained in advance according to experimental calibration;
a SOC value to be displayed obtain unit configured to apply the correction coefficient k obtained by the correction coefficient calculation unit and calculate the SOC value to be displayed according to following formula after the determination result of the correction trigger condition determination unit determines that the correction trigger condition has been reached;
displayed SOC=SOC displayed before charging+SOC charged*k;
determine the sum of the SOC value displayed before charging and the SOC value charged as the SOC value to be displayed after the determination result of the correction trigger condition determination unit determines that the correction trigger condition is not reached.

9. The system according to claim 7, wherein the system further comprises:
a calibration unit configured to calculate a current SOC value by a voltage calibration method and determine a calculated current SOC value as the SOC value to be displayed when the SOC stage determination unit determines that sum is not in the predetermined charging platform area of the lithium battery.

10. The system according to claim 9, wherein the calibration unit further comprises:
a smoothing processing unit configured to compare the calculated current SOC value with a SOC value expected to be displayed in a previous week, obtain an intermediate value between the calculated current SOC value and the SOC value expected to be displayed in a previous week through a damping algorithm as the SOC value to be displayed if a difference between the calculated current SOC value and the SOC value expected to be displayed in a previous week is greater than a predetermined threshold.
